(19) United States
(12) Patent Application Publication
(10) Pub. No.: US 2024/0224492 A1
(43) Pub. Date: Jul. 4, 2024

(54) SEMICONDUCTOR DEVICE

(71) Applicant: Socionext Inc., Kanagawa (JP)

(72) Inventors: Atsushi OKAMOTO, Yokohama (JP); Wenzhen WANG, Yokohama (JP); Hirotaka TAKENO, Yokohama (JP)

(21) Appl. No.: 18/606,421

(22) Filed: Mar. 15, 2024

Related U.S. Application Data
(63) Continuation of application No. PCT/JP2022/036488, filed on Sep. 29, 2022.
(60) Provisional application No. 63/261,847, filed on Sep. 30, 2021.

(51) Int. Cl. H10B 10/00

(52) U.S. Cl. CPC H10B 10/18

(57) ABSTRACT

A semiconductor device includes first and second power supply lines and first and second ground lines provided on a first surface of a substrate, and third and fourth power supply lines provided on a second surface of the substrate. The second power supply line and the third power supply line are connected through vias provided in the substrate. The semiconductor device includes first and second areas arranged to have a third area sandwiched in-between, and a power switch circuit including switch transistors connected between the third and fourth power supply lines.

### CROSS-REFERENCE TO RELATED APPLICATIONS

This U.S. non-provisional application is a continuation application of and claims the benefit of priority under 35 U.S.C. § 365 (c) from PCT International Application PCT/JP2022/036488 filed on Sep. 29, 2022, which is designated the U.S., and is based on and claims priority to U.S. provisional application No. 63/261,847 filed on Sep. 30, 2021, the entire contents of which are incorporated herein by reference.

### TECHNICAL FIELD

The present disclosure relates to a semiconductor device.

### BACKGROUND ART

In an SRAM (Static Random Access Memory), in the case where arrangement of power supply lines is different between a bit cell area and a peripheral circuit area, in some cases, a separating area is provided to secure spacing between the bit cell area and the peripheral circuit area in plan view. A technique called BPR (Buried Power Rails) has been known, in which the power supply lines are buried in a semiconductor substrate. In order to switch between supply and cutoff of a power supply voltage to a virtual power supply line of an internal circuit, a technique that provides a power switch circuit between a power supply line and the virtual power supply line has been known. A technique called BS-PDN (Backside-Power Delivery Network) has been known in which a power supply line network is provided on the back surface of a semiconductor substrate, and a power supply voltage is supplied through a via that penetrates the back surface and the top surface of the semiconductor substrate. Techniques that provide a transistor in an interconnect layer to switch between supply and cutoff of a power supply voltage have been known.

### RELATED ART DOCUMENTS

### Patent Documents

[Patent Document 1] U.S. Pat. No. 10,446,224
[Patent Document 2] U.S. Pat. No. 8,670,265
[Patent Document 3] US Patent Publication No. 2020/0135718
[Patent Document 4] US Patent Publication No. 2018/0151494
[Patent Document 5] US Patent Publication No. 2005/0212018
[Patent Document 6] U.S. Pat. No. 10,170,413
[Patent Document 7] WO2021/070366
[Patent Document 8] WO2021/070367
[Patent Document 9] WO2021/079511
[Patent Document 10] WO2021/111604

In the case where a transistor is formed using an interconnect layer in which BS-PDN interconnects are provided, detailed technical studies on how to arrange the power switch circuit have not been carried out.

### SUMMARY

According to one aspect in the present disclosure, a semiconductor device includes a substrate including a first surface and a second surface opposite to the first surface; a first power supply line provided on the first surface; a first ground line provided on the first surface; a first area including the first power supply line and the first ground line; a second power supply line provided on the first surface; a second ground line provided on the first surface; a third power supply line provided on the second surface; a fourth power supply line provided on the second surface; a via provided in the substrate, to electrically connect the second power supply line and the third power supply line; a second area including the second power supply line and the second ground line; a third area positioned between the first area and the second area in plan view; and a first power switch circuit including a first switch transistor electrically connected between the third power supply line and the fourth power supply line, the first switch transistor being provided on the second surface side of the substrate.

### BRIEF DESCRIPTION OF DRAWINGS

FIG. 1 is a plan view illustrating an overview of a layout of a semiconductor device in a first embodiment;

FIG. 2 is a circuit block diagram illustrating an overview of a power switch circuit arranged in a bit cell area in FIG. 1;

FIG. 3 is a plan view illustrating an example of a layout of power supply lines in an area where a power switch circuit in FIG. 1 is arranged;

FIG. 4A is a cross-sectional view illustrating an example of a cross section of an area that includes a switch transistor of a power switch circuit PSW1 in FIG. 3;

FIG. 4B is a cross-sectional view illustrating another example of a cross section of the switch transistor of the power switch circuit PSW1 in FIG. 3;

FIG. 4C is a cross-sectional view illustrating another example of a cross section of the switch transistor of the power switch circuit PSW1 in FIG. 3;

FIG. 4D is a cross-sectional view illustrating yet another example of a cross section of the switch transistor of the power switch circuit PSW1 in FIG. 3;

FIG. 5 is a diagram illustrating an example of a bit cell arranged in the bit cell area in FIG. 1;

FIG. 6 is a diagram illustrating another example of a bit cell arranged in the bit cell area in FIG. 1;

FIG. 7 is a plan view illustrating an example of a power switch circuit arranged to have a separating area and a bit cell area sandwiched in-between;

FIG. 8 is a cross-sectional view illustrating a cross section along a line Y1-Y1′ in FIG. 7;

FIG. 9 is a cross-sectional view illustrating a cross section along a line X1-X1′ in FIG. 7;

FIG. 10 is a plan view illustrating a modified example of the power switch circuit arranged in the bit cell area in FIG. 7;

FIG. 11 is a plan view illustrating an example of a power switch circuit arranged to have a separating area and a bit cell area sandwiched in-between in a semiconductor device according to a second embodiment; and

FIG. 12 is a plan view illustrating a modified example of a power switch circuit in FIG. 11.

### DESCRIPTION OF EMBODIMENTS

In the following, embodiments will be described with reference to the drawings.

According to the disclosed techniques, a power supply switch can be appropriately arranged in a semiconductor device, by using an interconnect layer in which interconnects of a power supply interconnect network of the bottom surface of a substrate are provided.

In the following, a reference numeral denoting a signal may also be used for denoting a signal value, a signal line, or a signal terminal. A reference numeral denoting a power supply may also be used for denoting a power supply voltage, a power supply line or a power supply terminal to which the power supply voltage is supplied.

### First Embodiment

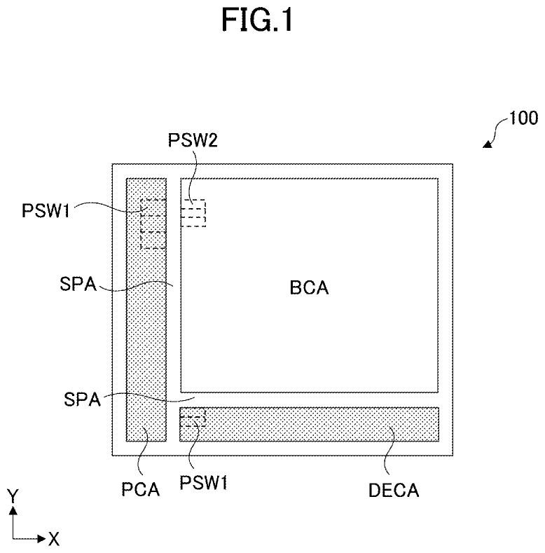

FIG. 1 is a plan view illustrating an overview of a layout of a semiconductor device in a first embodiment. A semiconductor device 100 illustrated in FIG. 1 is, for example, an SRAM. The semiconductor device 100 includes a bit cell area BCA, and a peripheral circuit area PCA and a decoder area DECA arranged peripheral to the bit cell area BCA. The peripheral circuit area PCA and the decoder area DECA constitute an example of a first area. The bit cell area BCA is an example of a second area.

For example, the peripheral circuit area PCA and the bit cell area BCA are arranged side by side in the X direction, and the decoder area DECA and the bit cell area BCA are arranged side by side in the Y direction. The X direction is an example of a first direction. The Y direction is an example of a second direction different from the first direction. In plan view, the separating area SPA is arranged between the bit cell area BCA, the peripheral circuit area PCA, and the decoder area DECA. The separating area SPA is an example of a third area.

For example, respective power supply voltages different from one another are supplied to the bit cell area BCA, the peripheral circuit area PCA, and the decoder area DECA. For example, multiple power supply lines extending in the X direction and arranged side by side in the Y direction are arranged in the bit cell area BCA, the peripheral circuit area PCA, and the decoder area DECA. Note that the positions and arrangement spacing of the power supply lines in the bit cell area BCA, the peripheral circuit area PCA, and the decoder area DECA may be different from one another.

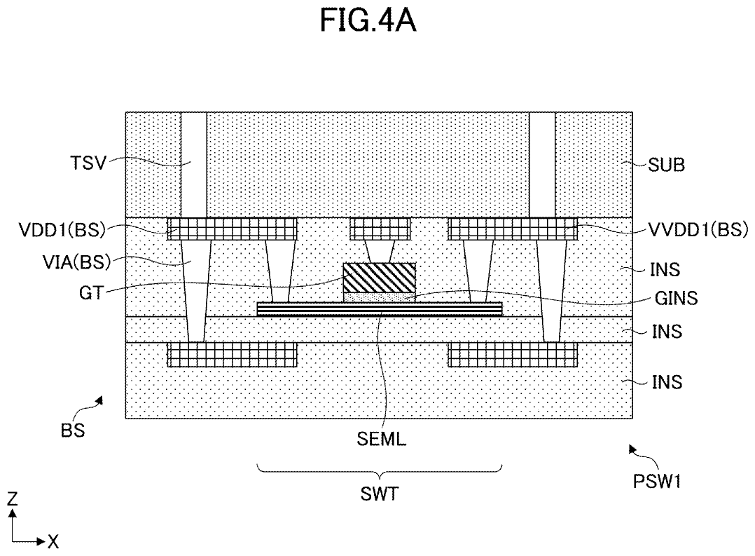

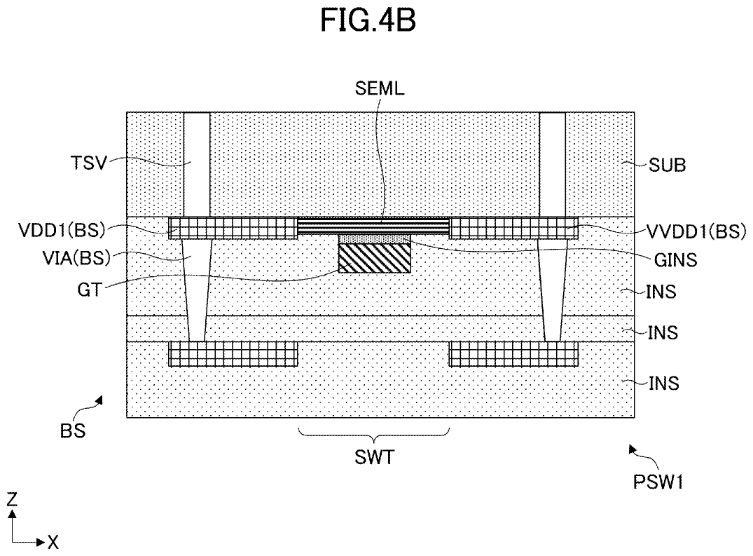

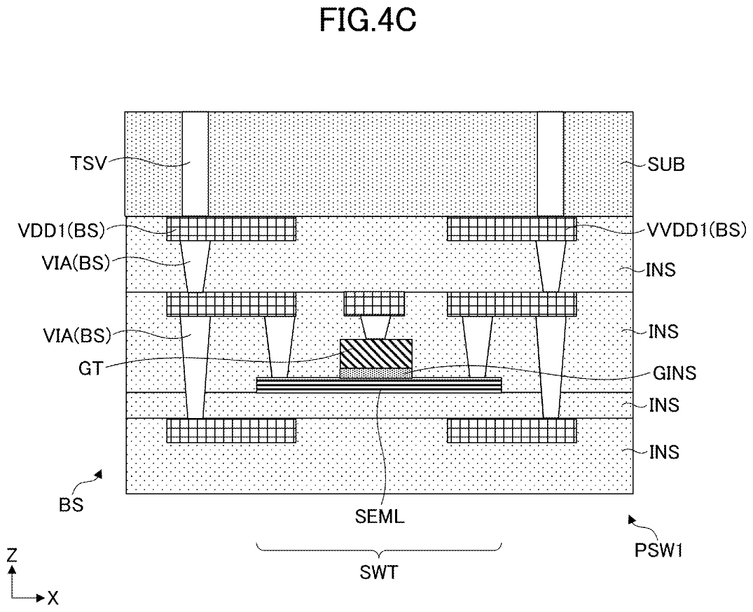

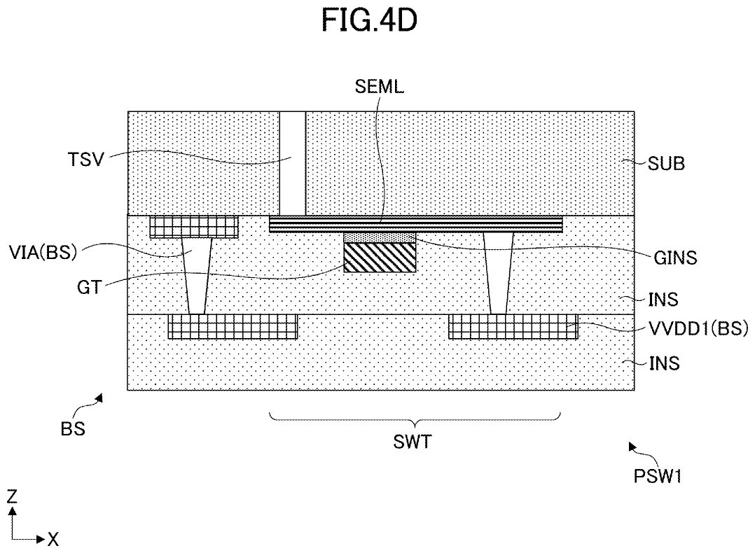

In addition, in each of the peripheral circuit area PCA and the decoder area DECA, a predetermined number of power switch circuits PSW1 are provided on the bottom surface (FIG. 4A) of the semiconductor substrate SUB of the semiconductor device 100. In the bit cell area BCA, a predetermined number of power switch circuits PSW2 are provided on the bottom surface of the semiconductor substrate SUB. Note that one of or both of the power switch circuits PSW1 and PSW2 may be arranged on the bottom surface BS of the semiconductor substrate SUB in the separating area SPA. The bottom surface BS of the semiconductor substrate SUB is an example of a second surface opposite to the top surface of the semiconductor substrate SUB. The power switch circuit PSW1 is an example of a second power switch circuit. The power switch circuit PSW2 is an example of a first power switch circuit. In the following, in the case where the power switch circuits PSW1 and PSW2 are referred to without distinction, these circuits may also be referred to as the power switch circuit (s) PSW.

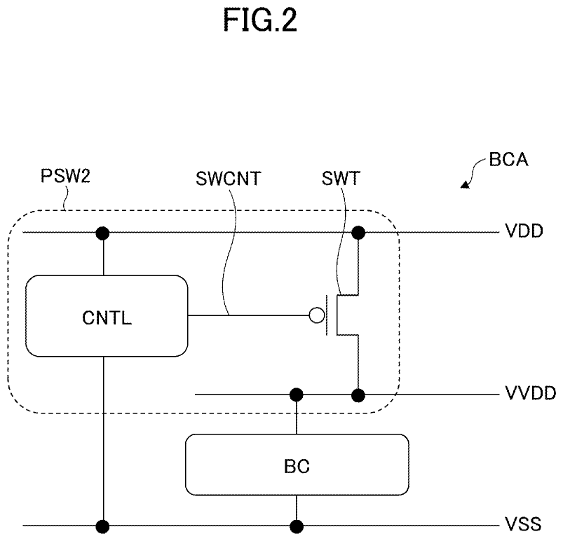

FIG. 2 is a circuit block diagram illustrating an overview of the power switch circuit PSW2 arranged in the bit cell area BCA in FIG. 1. Note that the power switch circuit PSW1 arranged in the peripheral circuit area PCA and the decoder area DECA also have substantially the same circuit configurations as in FIG. 2. The bit cell area BCA has multiple bit cells BC (i.e., memory cells). Each bit cell BC is electrically connected to the virtual power supply line VVDD and the ground line VSS, and operates by receiving power from the virtual power supply line VVDD.

The power switch circuit PSW2 includes a switch transistor SWT and a control circuit CNTL. The switch transistor SWT is, for example, a p-channel transistor, and operates by receiving at the gate a switch control signal SWCNT from the control circuit CNTL. The switch transistor SWT of the power switch circuit PSW2 is an example of a first switch transistor. The switch transistor SWT of the power switch circuit PSW1 is an example of a second switch transistor. Note that, for the sake of simplification, although one switch transistor SWT is illustrated in FIG. 2, multiple switch transistors SWT may be arranged between the power supply line VDD and the virtual power supply line VVDD.

While the switch transistor SWT is on, the power supply line VDD and the virtual power supply line VVDD are electrically connected, and the power supply voltage VDD is supplied to the virtual power supply line VVDD. While the switch transistor SWT is off, the electrical connection between the power supply line VDD and the virtual power supply line VVDD is cut off, and the virtual power supply line VVDD is set to a floating state.

The control circuit CNTL is, for example, a buffer circuit. In the case of causing the SRAM to operate, the control circuit CNTL sets the switch control signal SWCNT to a low level, to supply the power supply voltage from the power supply line VDD to the virtual power supply line VVDD. In the case of causing the SRAM to stop operating, the control circuit CNTL sets the switch control signal SWCNT to a high level to stop supplying the power supply voltage from the power supply line VDD to the virtual power supply line VVDD.

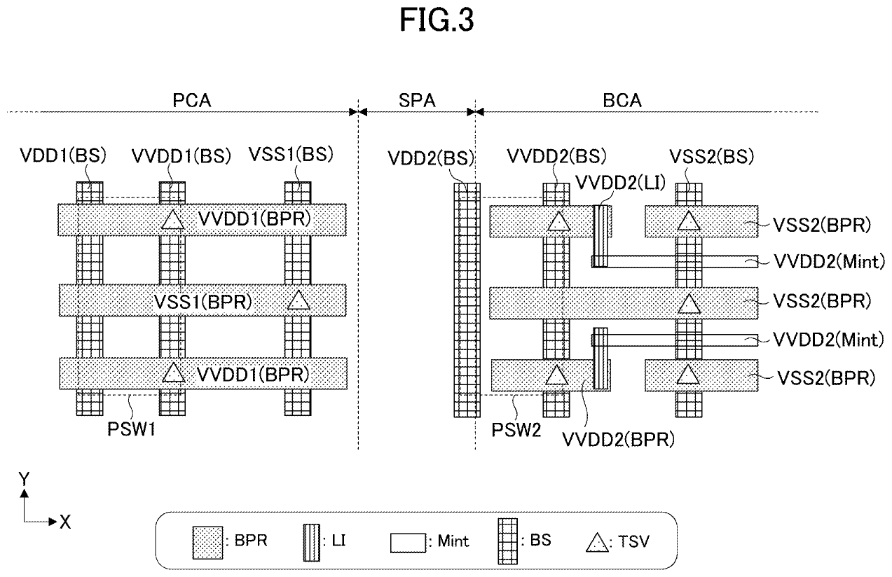

FIG. 3 is a plan view illustrating an example of a layout of power supply interconnects in the area where the power switch circuits PSW1 and PSW2 in FIG. 1 are arranged. FIG. 3 is an enlarged view of an area where the peripheral circuit area PCA and the bit cell area BCA are arranged to have the separating area SPA sandwiched in-between.

In the example illustrated in FIG. 3, interconnects of the Mint layer and the BPR are respectively provided extending in the X direction, and a local interconnect LI and interconnects of the bottom surface BS of the semiconductor substrate SUB are respectively provided extending in the Y direction. For example, the Mint layer is provided on the top surface side of the semiconductor substrate SUB. The local interconnect LI is provided between the semiconductor substrate SUB and the Mint layer. The top surface of the semiconductor substrate SUB is an example of a first surface.

In the following, power supply lines, virtual power supply lines, and ground lines routed in the peripheral circuit area PCA and the decoder area DECA are denoted by VDD1, VVDD1, and VSS1, respectively. Power supply lines, virtual power supply lines, and ground lines routed in the bit cell area BCA are denoted by VDD2, VVDD2, and VSS2, respectively. Note that the power supply lines or ground lines routed in the peripheral circuit area PCA or the bit cell area BCA may be arranged on the separating area SPA side.

A circuit arranged in the peripheral circuit area PCA and the decoder area DECA is electrically connected to the virtual power supply line VVDD1 and the ground line VSS1. A bit cell arranged in the bit cell area BCA is electrically connected to the virtual power supply line VVDD2 and the ground line VSS2. In the example illustrated in FIG. 3, the power switch circuit PSW1 is electrically connected to the power supply line VDD1, the virtual power supply line VVDD1, and the ground line VSS1; and the power switch circuit PSW2 is electrically connected to the power supply line VDD2, the virtual power supply line VVDD2, and the ground line VSS2.

In the peripheral circuit area PCA, the ground line VSS1(BPR) and the virtual power supply line VVDD1(BPR) provided as the BPR, and the ground line VSS1(BS), the power supply line VDD1(BS), and the virtual power supply line VVDD1(BS) provided on the bottom surface are arranged. The ground lines VSS1(BPR) and VSS1(BS) are connected to each other through TSVs. The virtual power supply lines VVDD1(BPR) and VVDD1(BS) are connected to each other through TSVs.

In the peripheral circuit area PCA, the bottom surface BS of the semiconductor substrate SUB is provided with a power switch circuit PSW1 that has a switch transistor (not illustrated) electrically connected to the power supply line VDD1(BS) and the virtual power supply line VVDD1(BS). The power switch circuit PSW1 supplies the power supply voltage VVDD1 to elements and circuits (not illustrated) provided in the peripheral circuit area PCA.

In the bit cell area BCA, the ground line VSS2(BPR) and the virtual power supply line VVDD2(BPR) provided as the BPR, and the ground line VSS(BS) and the virtual power supply line VVDD2(BS) provided on the bottom surface are arranged. The ground lines VSS2(BPR) and VSS2(BS) are connected to each other through TSVs. The virtual power supply lines VVDD2(BPR) and VVDD2(BS) are connected to each other through TSVs. The virtual power supply line VVDD2(BPR) is connected to the virtual power supply line VVDD2(Mint) of the Mint layer through the virtual power supply line VVDD2 of the local interconnect LI. The virtual power supply line VVDD2(Mint) is an example of a first interconnect.

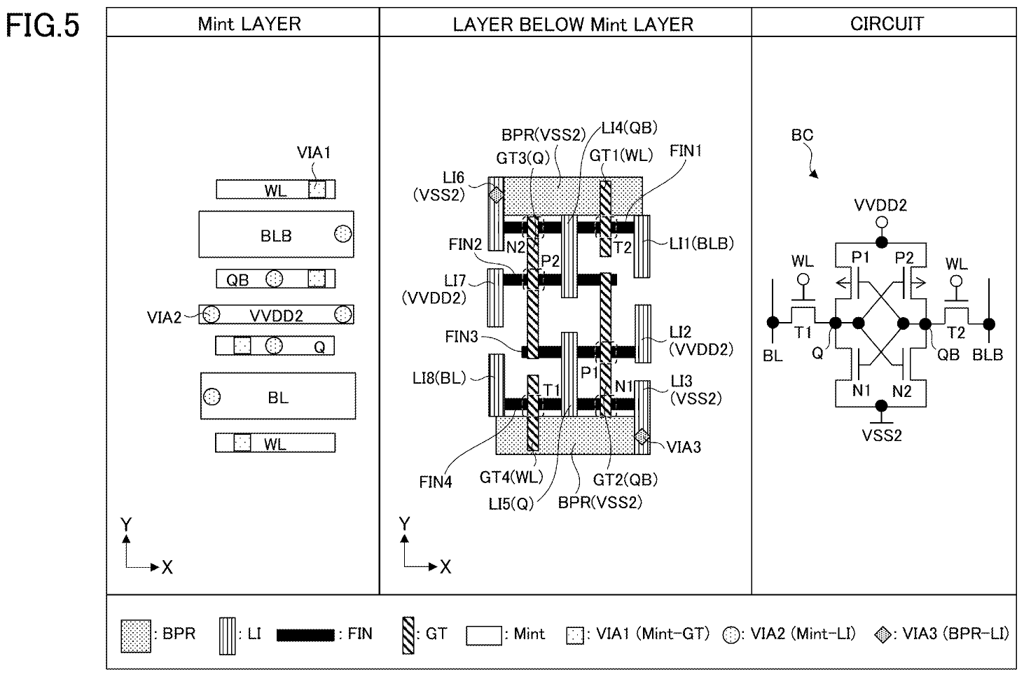

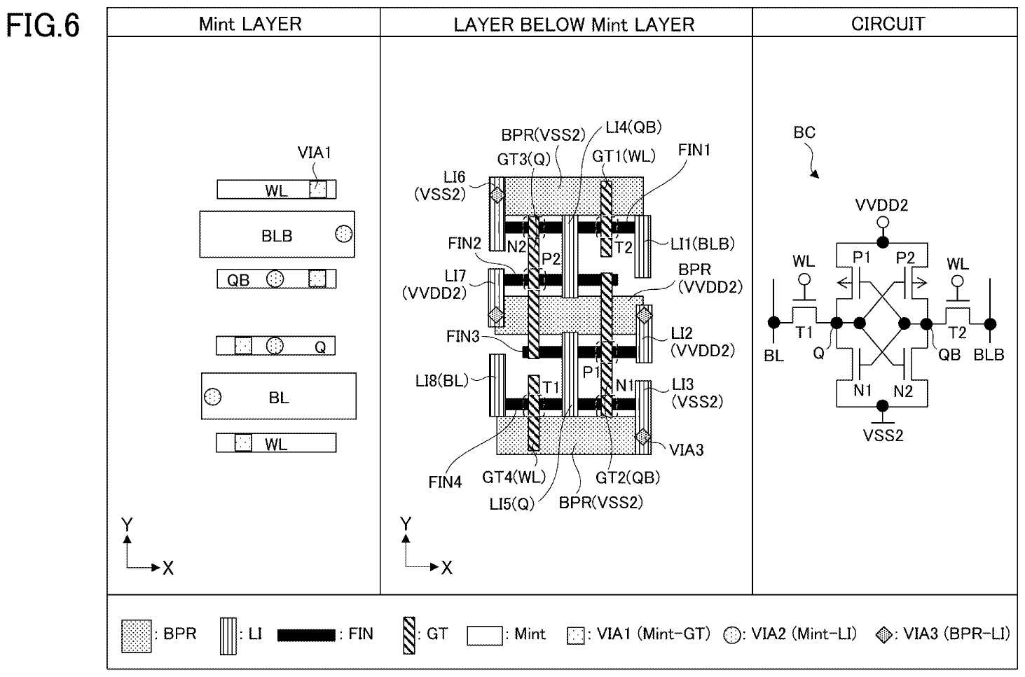

In the separating area SPA, a power supply line VDD2(BS) provided on the bottom surface is arranged. In the bit cell area BCA, the bottom surface BS of the semiconductor substrate SUB is provided with a power switch circuit PSW2 that has a switch transistor (not illustrated) electrically connected to the power supply line VDD2(BS) and the virtual power supply line VVDD2(BS). The power switch circuit PSW2 supplies the power supply voltage VVDD2 to the bit cell BC (FIG. 5 or FIG. 6) provided in the bit cell area BCA.

Note that the same power supply voltage may be supplied to the power supply line VDD1(BS) of the power switch circuit PSW1 and the power supply line VDD2(BS) of the power switch circuit PSW2 illustrated in FIG. 3, or different power supply voltages may be supplied to the respective lines. In the case where the same power supply voltage is supplied to the power supply lines VDD1(BS) and VDD2(BS), the power supply lines VDD1(BS) and VDD2(BS) may be electrically connected to each other. For example, the power supply line VDD1(BS), the virtual power supply line VVDD1(BS), the ground line VSS1(BS), the power supply line VDD2(BS), the virtual power supply line VVDD2(BS), and the ground line VSS2(BS) may be provided as a BS-PDN.

The virtual power supply line VVDD1(BPR) is an example of a first power supply line. The virtual power supply line VVDD2(BPR) is an example of a second power supply line. The virtual power supply line VVDD2(BS) is an example of a third power supply line. The power supply line VDD2(BS) is an example of a fourth power supply line. The virtual power supply line VVDD1(BS) is an example of a fifth power supply line. The power supply line VDD1(BS) is an example of a sixth power supply line. The ground line VSS1(BPR) is an example of a first ground line. The ground line VSS2(BPR) is an example of a second ground line. The ground line VSS1(BS) is an example of a third ground line. The ground line VSS2(BS) is an example of a fourth ground line.

FIG. 4A is a cross-sectional view illustrating an example of a cross section of an area that includes the switch transistor SWT of the power switch circuit PSW1 in FIG. 3. In FIG. 4A, only a structure of the semiconductor substrate SUB and the bottom surface BS side of the semiconductor substrate SUB is illustrated, and as such, transistors, interconnects, and the like provided on the top surface side of the semiconductor substrate SUB are omitted. Note that the cross-sectional structure of an area that includes the switch transistor SWT of the power switch circuit PSW2 in FIG. 3 is also substantially the same as in FIG. 4A.

The switch transistor SWT includes a semiconductor layer SEML, a gate insulation film GINS, and a gate electrode GT that are laminated with one another. A power supply line VDD1(BS) is connected to the semiconductor layer SEML at one side relative to the gate electrode GT. A virtual power supply line VVDD1(BS) is connected to the semiconductor layer SEML at the other side relative to the gate electrode GT. The switch transistor SWT is on or off by a control signal input to the gate electrode GT, and supplies a power supply voltage from the power supply line VDD1 to the virtual power supply line VVDD1 when being on.

Note that as illustrated in FIG. 4A, one of or both of the power supply line VDD1 and/or the virtual power supply line VVDD1 may be connected to an interconnect provided in an interconnect layer below the switch transistor SWT. In this case, an interconnect of the upper interconnect layer and an interconnect of the lower interconnect layer are connected to each other through a via VIA(BS) provided by opening the insulation film INS.

In addition, in FIG. 4A, although two interconnect layers are provided on the bottom surface BS of the semiconductor substrate SUB, three or more interconnect layers may be provided. In this case, interconnects of the two interconnect layers laminated to each other may be connected through vias VIA(BS) provided by opening the insulation film INS.

FIG. 4B is a cross-sectional view illustrating another example of a cross section of the switch transistor of the power switch circuit PSW1 in FIG. 3. Also in FIG. 4B, only a structure of the semiconductor substrate SUB and the bottom surface BS side of the semiconductor substrate SUB is illustrated, and as such, transistors, interconnects, and the like provided on the top surface side of the semiconductor substrate SUB are omitted. Note that the cross-sectional structure of an area that includes the switch transistor SWT of the power switch circuit PSW2 in FIG. 3 is also substantially the same as in FIG. 4B.

In FIG. 4B, the semiconductor layer SEML is provided in the same layer as the power supply line VDD1(BS) and the virtual power supply line VVDD1(BS), and the gate insulation film GINS and the gate electrode GT are provided on the bottom surface BS of the semiconductor layer SEML. The power supply line VDD1(BS) and the virtual power supply line VVDD1(BS) are respectively connected to the semiconductor layer SEML. The semiconductor layer SEML, the gate insulation film GINS, and the gate electrode GT are provided in this order toward the bottom surface BS. The rest of the structure is substantially the same as in FIG. 4A. For example, the gate electrode GT extends in the depth direction in FIG. 4B and is connected to an interconnect provided on the bottom surface.

FIG. 4C is a cross-sectional view illustrating another example of a cross section of the switch transistor of the power switch circuit PSW1 in FIG. 3. Also in FIG. 4C, only a structure of the semiconductor substrate SUB and the bottom surface BS side of the semiconductor substrate SUB is illustrated, and as such, transistors, interconnects, and the like provided on the top surface side of the semiconductor substrate SUB are omitted. Note that the cross-sectional structure of an area that includes the switch transistor SWT of the power switch circuit PSW2 in FIG. 3 is also substantially the same as in FIG. 4C. FIG. 4C illustrates a structure substantially the same as in FIG. 4A, except that the switch transistor SWT is provided in the second layer instead of the top layer closest to the semiconductor substrate SUB.

FIG. 4D is a cross-sectional view illustrating yet another example of a cross section of the switch transistor SWT of the power switch circuit PSW1 in FIG. 3. Also in FIG. 4D, only a structure of the semiconductor substrate SUB and the bottom surface BS side of the semiconductor substrate SUB is illustrated, and as such, transistors, interconnects, and the like provided on the top surface side of the semiconductor substrate SUB are omitted. Note that the cross-sectional structure of an area that includes the switch transistor SWT of the power switch circuit PSW2 in FIG. 3 is also substantially the same as in FIG. 4D.

FIG. 4D illustrates a structure substantially the same as in FIG. 4A, except that the semiconductor layer SEML, the gate insulation film GINS, and the gate electrode GT are sequentially provided in this order from the bottom surface BS, and one side of the semiconductor layer SEML is connected to the top surface side of the semiconductor substrate SUB through a TSV.

The one side of the semiconductor layer SEML is connected to the virtual power supply line VVDD1 provided on the top surface side of the semiconductor substrate SUB through a TSV. The other side of the semiconductor layer SEML is connected to the power supply line VVDD1(BS) provided in the interconnect layer below the switch transistor SWT through a via VIA(BS).

Note that the semiconductor layer SEML illustrated in FIGS. 4A to 4D may be provided using graphene or carbon nanotubes. In addition, the switch transistor SWT illustrated in FIGS. 4A to 4D may be a thin-film transistor (TFT).

FIG. 5 is a diagram illustrating an example of the bit cell BC arranged in the bit cell area BCA in FIG. 1. In order to make the layout of the interconnects easier to understand, the left box in FIG. 5 illustrates a layout of interconnects in the Mint layer and vias connected to the Mint layer; and the middle box in FIG. 5 illustrates a layout of interconnects, gates, fins, and vias in a layer below the Mint layer (on the semiconductor substrate side). In addition, the right box in FIG. 5 illustrates a circuit of the bit cell BC. The layouts illustrated in the left and middle boxes in FIG. 5 are positioned to overlap each other in plan view.

A via VIA1 illustrated as a square connects an interconnect in the Mint layer to a corresponding gate. A via VIA2 illustrated as a circle connects an interconnect in the Mint layer to a local interconnects LI. A via VIA3 illustrated as a diamond connects a local interconnect LI to an interconnect of the BPR. A local interconnect LI and a fin FIN are connected at positions that overlap in plan view.

Dashed-line rectangles illustrated in the middle box in FIG. 5 indicate p-channel transistors P1 and P2, n-channel transistors N1 and N2, and transfer transistors T1 and T2. The transfer transistors T1 and T2 are n-channel transistors. Reference numerals Q and QB illustrated in the left, middle, and right boxes in FIG. 5 indicate complementary storage nodes of the bit cell BC. A storage node Q is connected to a bit line BL through the transfer transistor T1. A storage node QB is connected to a bit line BLB through the transfer transistor T2.

Two word lines WL provided in the Mint layer are connected to gates GT4 and GT1 of the transfer transistors T1 and T2 through the vias VIA1, respectively. A virtual power supply line VVDD2 provided in the Mint layer is connected to local interconnects LI2 and LI7 through the vias VIA2. The local interconnect LI2 is connected to the source of the p-channel transistor P1. The local interconnect LI7 is connected to the source of the p-channel transistor P2.

An interconnect Q provided in the Mint layer is connected to a local interconnect LI5 and fins FIN3 and FIN4 through the via VIA2, and to a gate GT3 through the via VIA1. The fin FIN3 functions as the source and the drain of the p-channel transistor P1, and the fin FIN4 functions as the source and the drain of the transfer transistor T1 and the n-channel transistor N1.

An interconnect QB provided in the Mint layer is connected to a local interconnect LI4 and fins FIN2 and FIN1 through the via VIA2, and to a gate GT2 through the via VIA1. The fin FIN2 functions as the source and the drain of the p-channel transistor P2, and the fin FIN1 functions as the source and the drain of the transfer transistor T2 and the n-channel transistor N2.

The bit line BLB provided in the Mint layer is connected to the local interconnect LIL and the fin FIN1 through the via VIA2. The bit line BL provided in the Mint layer is connected to the local interconnect LI8 and the fin FIN4 through the via VIA2. The ground lines VSS2 of the two BPR arranged on both sides in the Y direction in the middle box in FIG. 5 are connected to the local interconnects LI3 and LI6 through the vias VIA3, respectively. The local interconnect LI3 is connected to the source of the n-channel transistor N1. The local interconnect LI6 is connected to the source of the n-channel transistor N2.

FIG. 6 is a diagram illustrating another example of the bit cell BC arranged in the bit cell area BCA in FIG. 1. Elements that are substantially the same as in FIG. 5 are assigned the same reference numerals or the same patterns, and detailed description thereof is omitted. FIG. 6 illustrates a layout substantially the same as in FIG. 5 except that the virtual power supply line VVDD2 is provided in the BPR.

In addition, the virtual power supply lines VVDD2 of the local interconnects LI2 and LI7 are connected to the virtual power supply lines VVDD2 of the BPR through the via VIA3. The virtual power supply line VVDD2 of the BPR is arranged between the ground lines VSS2 of the two BPR, and extends in the X direction, similar to the ground lines VSS2 of the two BPR.

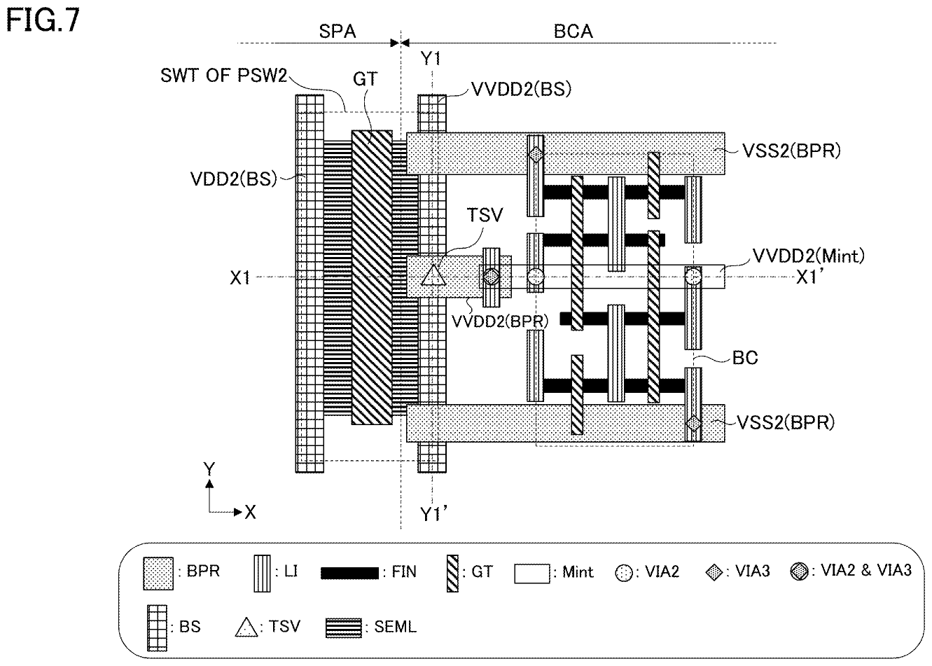

FIG. 7 is a plan view illustrating an example of a power switch circuit PSW2 arranged to have a separating area SPA and a bit cell area BCA sandwiched in-between. The switch transistor SWT of the power switch circuit PSW2 illustrated in FIG. 2 is provided in the separating area SPA. For example, the bit cell BC illustrated in FIG. 5 is arranged in the bit cell area BCA. Note that part of the interconnects and vias of the bit cell BC in the bit cell area BCA are not illustrated.

In the semiconductor layer SEML of the switch transistor SWT2 (FIGS. 4A to 4D), one side relative to the gate electrode GT is connected to the power supply line VDD2(BS) of the bottom surface BS of the semiconductor substrate SUB. In addition, in the semiconductor layer SEML of the switch transistor SWT2, the other side relative to the gate electrode GT is connected to the virtual power supply line VVDD2(BS) of the bottom surface BS. Note that in FIG. 7, an interconnect connected to the gate electrode GT is omitted.

The virtual power supply line VVDD2(BS) of the bottom surface BS is connected to the virtual power supply line VVDD2(Mint) of the Mint layer through the TSV and the virtual power supply line VVDD2(BPR). Note that in the case where the power switch circuit PSW2 is arranged in the bit cell area BCA, the virtual power supply line VVDD2(BPR) and the ground line VSS2(BPR) may extend over the switch transistor SWT2 provided on the bottom surface. Note that multiple ground lines VSS(BPR) of the bit cell area BCA may be connected to each other through the ground lines VSS2(BS) and TSVs of the bottom surface BS.

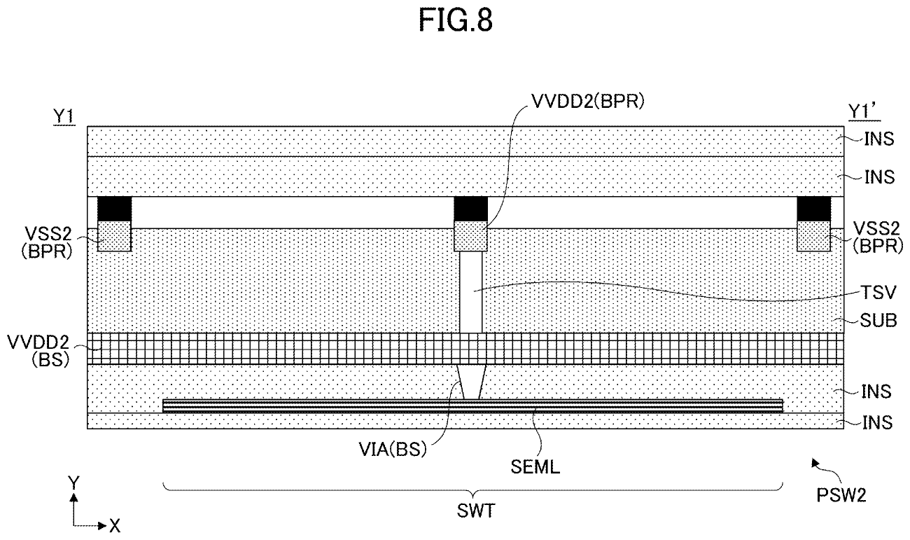

FIG. 8 is a cross-sectional view illustrating a cross section along a line Y1-Y1′ in FIG. 7. The virtual power supply line VVDD2(BS) of the bottom surface BS of the semiconductor substrate SUB is connected to the semiconductor layer SEML of the switch transistor SWT of the power switch circuit PSW2 through a via VIA(BS). In addition, the virtual power supply line VVDD2(BS) is connected to the virtual power supply line VVDD2(BPR) of the BPR through a TSV.

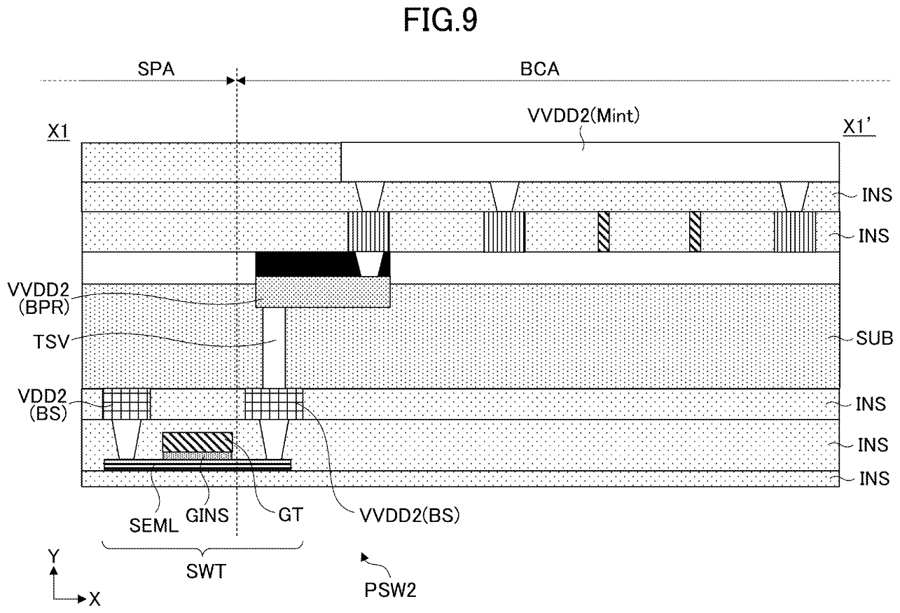

FIG. 9 is a cross-sectional view illustrating a cross section along a line X1-X1′ in FIG. 7. The switch transistor SWT2 includes a semiconductor layer SEML, a gate insulation film GINS, and a gate electrode GT that are laminated with one another as in FIG. 4A.

In the semiconductor layer SEML of the switch transistor SWT of the power switch circuit PSW2, one side relative to the gate electrode GT is connected to the virtual power supply line VVDD2(BS) of the bottom surface BS of the semiconductor substrate SUB. In the semiconductor layer SEML, the other side relative to the gate electrode GT is connected to the power supply line VDD2(BS) of the bottom surface BS of the semiconductor substrate SUB.

Note that the TSV connected to the virtual power supply line VVDD2(BS) of the bottom surface BS may be connected through to the virtual power supply line VVDD2(Mint) of the Mint layer. In addition, there may be TSVs connected through to interconnects of the BPR, and TSVs connected through to interconnects of the Mint layer.

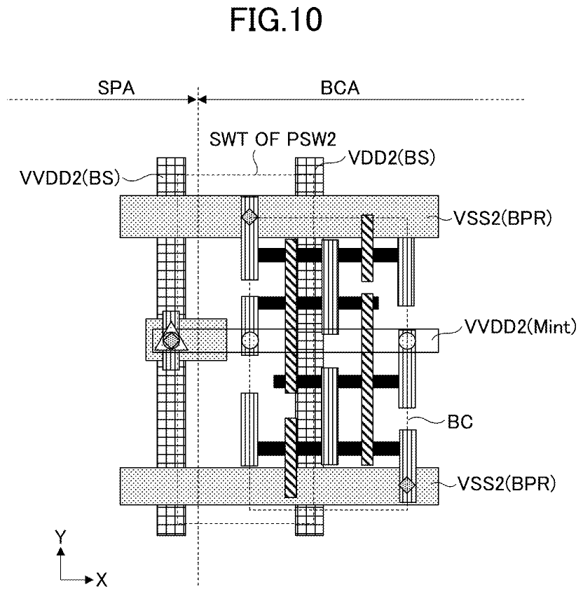

FIG. 10 is a plan view illustrating a modified example of the power switch circuit PSW2 arranged in the bit cell area BCA in FIG. 7. Elements that are substantially the same as in FIG. 7 are assigned the same reference numerals, and detailed description thereof is omitted.

In FIG. 10, the semiconductor layer SEML and the gate electrode GT of the switch transistor SWT are omitted. FIG. 10 illustrates a layout that is substantially the same as in FIG. 7 except that the power supply line VDD2(BS) of the switch transistor SWT of the power switch circuit PSW2 and the bottom surface BS of the semiconductor substrate SUB are arranged at positions overlapping the bit cell BC.

Note that the switch transistor SWT together with the virtual power supply line VVDD2(BS) may be arranged at a position overlapping the bit cell area BCA. In addition, multiple ground lines VSS(BPR) of the bit cell area BCA may be connected through TSVs to the common ground line VSS2(BS) of the bottom surface BS.

As above, in this embodiment, by using an interconnect layer provided on the bottom surface BS of the semiconductor substrate SUB, the power switch circuit PSW (or PSW1 and PSW2) can be appropriately arranged. For example, the power switch circuit PSW can be arranged in the bit cell area BCA or the separating area SPA. Alternatively, the power switch circuits PSW1 and PSW2 can be arranged in the peripheral circuit area PCA and the bit cell area BCA, respectively.

Further, the power supply voltage can be supplied from the power switch circuit PSW provided on the bottom surface BS to the virtual power supply lines VVDD of the peripheral circuit area PCA, the decoder area DECA, and the bit cell area BCA. In other words, the power supply voltage can be supplied to the SRAM from the power switch circuit PSW provided on the bottom surface BS.

### Second Embodiment

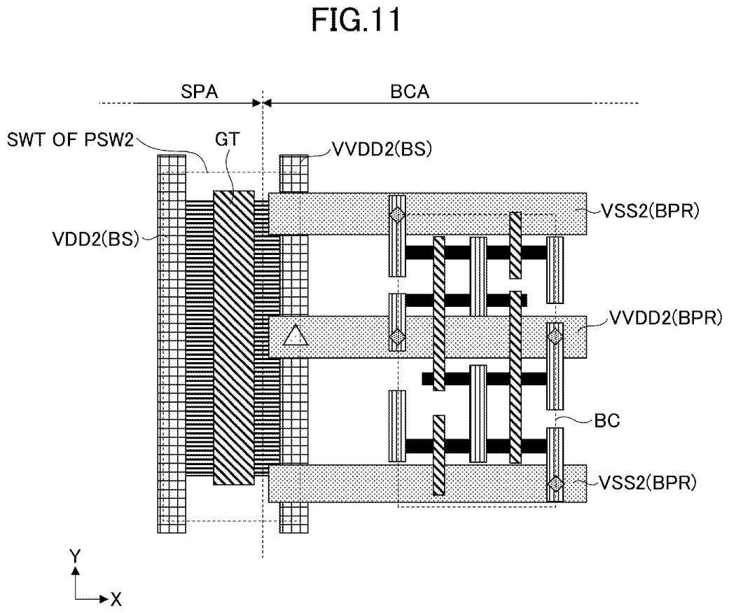

FIG. 11 is a plan view illustrating an example of a power switch circuit PSW2 arranged to have a separating area SPA and a bit cell area BCA sandwiched in-between in a semiconductor device according to a second embodiment. Elements that are substantially the same as in the embodiments described above are assigned the same reference numerals, and detailed description thereof is omitted. FIG. 11 is the same as FIG. 7 except that the virtual power supply line VVDD2 of the bit cell area BCA is provided using BPR.

Note that as illustrated in FIG. 10, the power supply line VDD2(BS) of the switch transistor SWT of the power switch circuit PSW2 and the bottom surface BS of the semiconductor substrate SUB may be arranged at positions overlapping the bit cell BC. In addition, in the case where the power switch circuit PSW2 is arranged in the bit cell area BCA, the virtual power supply line VVDD2(BPR) and the ground line VSS2(BPR) may extend over the switch transistor SWT. In addition, multiple ground lines VSS(BPR) of the bit cell area BCA may be connected through TSVs to the common ground line VSS2(BS) of the bottom surface BS.

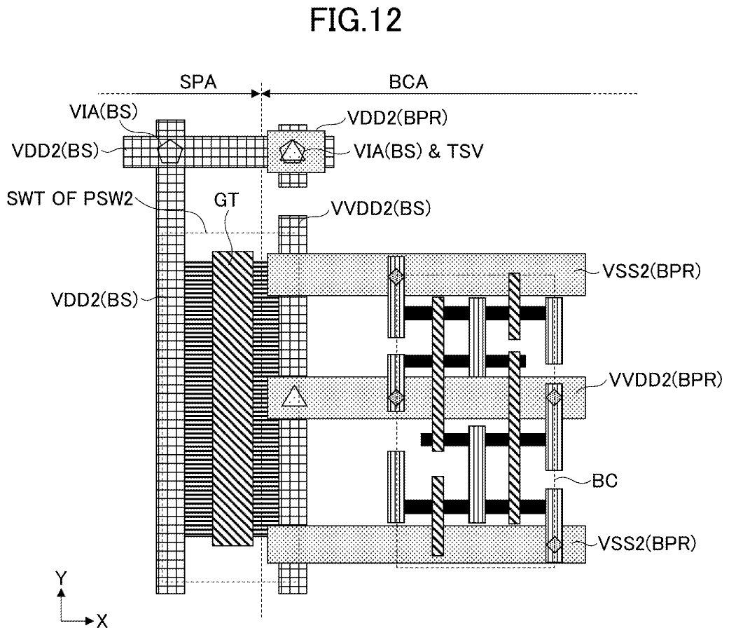

FIG. 12 is a plan view illustrating a modified example of the power switch circuit PSW2 in FIG. 11. Elements that are substantially the same as in FIG. 11 are assigned the same reference numerals, and detailed description thereof is omitted. In FIG. 12, the power supply line VDD2(BS) connected to the power switch circuit PSW2 is connected through a TSV to the power supply line VDD2(BPR) provided in the top surface of the semiconductor substrate SUB. The power supply line VDD2(BPR) is an example of a seventh power supply line.

A TSV connecting the power supply line VDD2(BS) to the power supply line VDD2(BPR) is arranged, for example, in the bit cell area BCA. Accordingly, interconnects of the BPR can be suppressed from being arranged in the separating area SPA. A pentagon illustrated at an intersection of a power supply line VDD2(BS) extending in the Y direction and a power supply line VDD2(BS) extending in the X direction is a via VIA(BS) that connects different interconnect layers in the bottom surface BS of the semiconductor substrate SUB.

Note that one of or both of the power supply line VDD2(BS) and the virtual power supply line VVDD2(BS) may be arranged in mesh by interconnects provided in multiple interconnect layers of the bottom surface BS. In this case, the interconnects of the multiple interconnect layers are connected to each other through vias VIA(BS). In addition, multiple ground lines VSS2(BPR) of the bit cell area BCA may be connected through TSVs to the common ground line VSS2(BS) of the bottom surface BS.

The layout configuration described in FIG. 12 may be applied to the other embodiments described above, and may be applied to the power supply line VDD1(PSW1) or the virtual power supply line VVDD1(PSW1) provided in the power switch circuit PSW1. Note that in the case where the layout configuration described in FIG. 12 is applied to the power switch circuit PSW1, the TSV connecting the power supply line VDD1(BS) of the bottom surface BS and the power supply line VDD1(BPR) of the top surface of the semiconductor substrate SUB is arranged in the peripheral circuit area PCA.

As above, the same effects can be obtained in this embodiment as in the embodiments described above. For example, by using an interconnect layer provided on the bottom surface BS of the semiconductor substrate SUB, the power switch circuit PSW2 can be appropriately arranged. For example, the power switch circuit PSW2 can be arranged in the bit cell area BCA or the separating area SPA.

As above, the present inventive concept has been described based on the respective embodiments; note that the present disclosure is not limited to the requirements set forth in the embodiments described above. These requirements can be changed within a scope to the extent that they do not depart from the gist of the present inventive concept, and can be suitably defined according to applications.

What is claimed is:

1. A semiconductor device comprising:
a substrate including a first surface and a second surface opposite to the first surface;
a first power supply line provided on the first surface;
a first ground line provided on the first surface;
a first area including the first power supply line and the first ground line;
a second power supply line provided on the first surface;
a second ground line provided on the first surface;
a third power supply line provided on the second surface;
a fourth power supply line provided on the second surface;
a via provided in the substrate, to electrically connect the second power supply line and the third power supply line;
a second area including the second power supply line and the second ground line;
a third area positioned between the first area and the second area in plan view; and
a first power switch circuit including a first switch transistor electrically connected between the third power supply line and the fourth power supply line, the first switch transistor being provided on the second surface side of the substrate.

2. The semiconductor device as claimed in claim 1, further comprising:
a first interconnect connected to the second power supply line.

3. The semiconductor device as claimed in claim 1, wherein the second power supply line extends in a first direction in the second area.

4. The semiconductor device as claimed in claim 1, wherein the first power switch circuit is provided in the second area in plan view.

5. The semiconductor device as claimed in claim 1, wherein the first power switch circuit is provided in the third area in plan view.

6. The semiconductor device as claimed in claim 1, further comprising:
a fifth power supply line provided on the second surface;
a sixth power supply line provided on the second surface;
a via provided in the substrate, to connect the fifth power supply line to the first power supply line provided on the first surface;
a second power switch circuit provided in the first area in plan view, and including a second switch transistor electrically connected between the fifth power supply line and the sixth power supply line, the second switch transistor being provided on the second surface side of the substrate.

7. The semiconductor device as claimed in claim 1, wherein the first ground line and the second ground line extend in a first direction, and are arranged with spacing in a second direction different from the first direction, and
wherein arrangement spacing of a plurality of first ground lines in the second direction is different from arrangement spacing of a plurality of second ground lines in the second direction.

8. The semiconductor device as claimed in claim 1, further comprising:
a third ground line provided on the second surface;
a fourth ground line provided on the second surface;
a via provided in the substrate, to connect the third ground line to the first ground line provided on the first surface; and
a via provided in the substrate, to connect the fourth ground line to the second ground line provided on the first surface.

9. The semiconductor device as claimed in claim 1, further comprising:
a seventh power supply line provided on the first surface,
wherein the fourth power supply line is connected to the seventh power supply line through a via provided in the substrate.

10. The semiconductor device as claimed in claim 6, wherein the sixth power supply line and the fourth power supply line are electrically connected to each other.
